(19) United States
(12) Patent Application Publication
(10) Pub. No.: US 2008/0067325 A1
(43) Pub. Date: Mar. 20, 2008

(54) PHOTO DETECTING APPARATUS

(75) Inventors: Kuniyuki Tani, Ogaki-shi (JP); Hajime Takashima, Atsugi-shi (JP); Atsushi Wada, Ogaki-city (JP)

Correspondence Address: DITTHAVONG MORI & STEINER, P.C., 918 Prince St., Alexandria, VA, 22314, US

(73) Assignee: Sanyo Electric Co., Ltd., Moriguchi-shi (JP)

(21) Appl. No.: 11/858,583

(22) Filed: Sep. 20, 2007

(30) Foreign Application Priority Data
Sep. 20, 2006 (JP) 2006-255073
Jul. 13, 2007 (JP) 2007-184217

(51) Int. Cl. H01L 27/144

(52) U.S. Cl. 250/208.1

(57) ABSTRACT

A plurality of pixel circuits, provided with a plurality of photo detecting elements, respectively, cause photocurrent corresponding to an incident light. The pixel circuits are placed on intersections of a plurality of data lines and scanning lines, respectively. A second capacitance charges and discharges an electric charge overflowing from a first capacitance caused by the photo detecting element. Each second capacitance is shared by a plurality of pixel circuits. A plurality of pixel circuits sharing the second capacitance are controlled so that exposure periods of the pixel circuits do not overlap with one another.

### CROSS-REFERENCE TO RELATED APPLICATIONS

This application is based upon and claims the benefit of priority from the prior Japanese Patent Applications No. 2006-255073, filed on Sep. 20, 2006, and Japanese Patent Application No. 2007-184217, filed Jul. 13, 2007, the entire contents of which are incorporated herein by reference.

### BACKGROUND OF THE INVENTION

1. Field of the Invention

The present invention relates to a CMOS image sensor and other photo detecting devices.

2. Description of the Related Art

In recent years, CCD (Charge Coupled Device) or CMOS (Complementary Metal Oxide Semiconductor) image sensors are used in a great deal of image pickup apparatuses, such as digital still cameras and digital video cameras.

A number of benefits can be gained by choosing a CMOS image sensor. For example, a CMOS image sensor can be produced on the same manufacturing line as general chips, and it can be packaged into a single chip together with the peripheral functions. Further, the CMOS image sensor is advantageous in that the CMOS image sensor can be driven at lower voltage than a CCD type and the CMOS image sensor consumes less power than the CCD type.

Each pixel of a CMOS sensor is constructed by including a photodiode and a switch using MOSFETs. A solid-state image sensor equipped with an overflow drain that sweeps out an excess charge occurring in the photodiode has been proposed. When the overflow drain is provided, the charge amount stored can be increased and therefore a wider dynamic range can be achieved.

However, the provision of an overflow drain capacity in the pixel circuit increases the area of pixel circuits. Since low-cost image sensors need to be supplied for use in vehicles, there is an increasing demand of suppressing the increase in the area occupied by the overflow drain capacity.

### SUMMARY OF THE INVENTION

A photo detecting apparatus according to one embodiment of the present invention comprises: a plurality of pixel circuits including a plurality of photo detecting elements, respectively, which cause photocurrent corresponding to an incident light; and a second capacitance which charges and discharges an electric charge overflowing from a first capacitance caused by each of the photo detecting elements. A pixel circuit where the photo detecting element is connected with the second capacitance and a pixel circuit where the photo detecting element is not connected with the second capacitance are mixed in the plurality of pixel circuits.

### BRIEF DESCRIPTION OF THE DRAWINGS

Embodiments will now be described by way of examples only, with reference to the accompanying drawings which are meant to be exemplary, not limiting and wherein like elements are numbered alike in several Figures in which:

FIG. 1 is a circuit diagram showing a whole structure of a photo detecting apparatus according to an embodiment of the present invention;

FIG. 2 is a circuit diagram showing a structure of a pixel circuit that constitutes a photo detecting apparatus according to an embodiment of the present invention;

FIG. 3 is an operational sequence diagram of each pixel circuit;

FIG. 4 illustrates a first operation example of a photo detecting apparatus;

FIG. 5 illustrates a third operation example of a photo detecting apparatus;

FIG. 6 illustrates the size of a dynamic range in each structure of the photo detecting apparatus 300 and a result of comparison among them;

FIG. 7 illustrates an image pickup area generated by a Bayer arrangement;

FIGS. 8A to 8F illustrate examples of arrangement where an overflow drain capacitor is shared;

FIG. 9 is a circuit diagram showing a structure of an image circuit according to a first modification;

FIG. 10 is a diagram showing a relationship between incident light intensity and stored charge amount at an overflow drain capacitor according to a first modification;

FIG. 11 is a circuit diagram showing a pixel circuit according to a second modification;

FIG. 12 is a circuit diagram showing a pixel circuit according to a third modification;

FIG. 13 is a diagram showing a relationship between incident light intensity and stored charge amount at an overflow drain capacitor according to a third modification;

FIG. 14 is a circuit diagram showing a structure of a photo detecting apparatus provided with a pixel circuit according to a third modification; and

FIG. 15 is a circuit diagram showing a structure of a photo detecting apparatus provided with a pixel circuit according to a fourth modification.

### DETAILED DESCRIPTION OF THE INVENTION

The invention will now be described by reference to the preferred embodiments. This does not intend to limit the scope of the present invention, but to exemplify the invention.

A description of a typical embodiment will be given before describing a detailed description of the present invention. A photo detecting apparatus according to one embodiment of the present invention comprises: a plurality of pixel circuits including a plurality of photo detecting elements, respectively, which cause photocurrent corresponding to an incident light; and a second capacitance which charges and discharges an electric charge overflowing from a first capacitance caused by each of the photo detecting elements. A pixel circuit where the photo detecting element is connected with the second capacitance and a pixel circuit where the photo detecting element is not connected with the second capacitance are mixed in the plurality of pixel circuits. The concept in “being connected” may include physical connection and electrical connection. The “first capacitance” may be charged or discharged by photocurrent flowing through the photo detecting element.

According to this embodiment, a pixel circuit of a type which is connected to the second capacitance and that which is not connected to the second capacitance are mixed. Thus the area occupied by the second capacitance can be made smaller. As a result, the dynamic range can be expanded while increase in circuit scale is being suppressed.

Another embodiment of the present invention relates also to a photo detecting apparatus. This apparatus comprises: a plurality of pixel circuits including a plurality of photo detecting elements, respectively, which cause photocurrent corresponding to an incident light; and a second capacitance which charges and discharges an electric charge overflowing from a first capacitance included in each of the photo detecting elements. Each second capacitance is shared by a plurality of pixel circuits.

According to this embodiment, the second capacitance is share by a plurality of pixel circuits. Thus the area of the second capacitance can be made smaller and the dynamic range can be expanded while the increase in circuit scale can be suppressed.

A plurality of pixel circuits sharing the second capacitance may be controlled so that exposure periods thereof do not overlap with one another. A plurality of pixel circuits sharing the second capacitance may share a data line. By employing this embodiment, the mixture of electric charge in a plurality of pixel circuit can be prevented and therefore the second capacitance can be shared while the signal accuracy is maintained.

A plurality of pixel circuits sharing the second capacitance may include a pixel circuit electrically conducting with the second capacitance and a pixel circuit not electrically conducting therewith, and the pixel circuit electrically conducting with the second capacitance may be switched frame by frame. The switching may be done for each frame or for every few frames. If the number of a plurality of pixel circuits that share the second capacitance is three or more, the second capacitance and the pixel circuit in a conducting state may be changed. By employing this embodiment, the position of a pixel circuit whose dynamic range has been expanded can be changed as appropriate. Thus a high-quality image can be obtained even in the case when an object with little movement is captured.

A plurality of pixel circuits constituting an image pickup area may include a plurality of kinds of pixel circuits that output different color signals, respectively, and the number of the plurality of kinds of pixel circuits conducting with the second capacitance may be retained at a predetermined ratio among frames. According to this embodiment, even if a pixel circuit that is to be electrically conductive with the second capacitance is switched frame by frame, the color balance can be maintained among frames.

A plurality of pixel circuits constituting an image pickup area may include a green pixel circuit for outputting a signal corresponding to a green component, a blue pixel circuit for outputting a signal corresponding to a blue component and a red pixel circuit for outputting a read component, and the number of green pixel circuits electrically conducting with the second capacitance may be greater than or equal to the total number of blue pixel circuits and red pixel circuit circuits electrically conducting with the second capacitance. The ratio of the green pixel circuit, the blue pixel circuit and the red pixel circuit electrically conducting respectively with the second capacitor may be 2:1:1. By employing this embodiment, the dynamic range of green signal which is highly sensitive to the human eyes can be expanded by more pixels. As a result, the apparent resolution can be improved.

An output value of a saturating pixel circuit may estimated from an output value of a surrounding nonsaturated pixel circuit. If a pixel circuit which is not connected with the second capacitance or a nonconductive pixel circuit has saturated, the output value of said pixel circuit may be estimated from the output value of a nonsaturated pixel circuit surrounding said pixel circuit. According to this embodiment, even though the area of the second capacitance is made smaller, the dynamic range can be maintained or expanded.

The photo detecting apparatus may further comprise: a current control element, connected to a terminal of said second capacitance on a side where the electric charge flows in, which delivers a current to cancel part of an electric charge when the electric charge overflowing from the first capacitance is stored in the second capacitance; and a detection circuit which detects a signal corresponding to an electric charge stored in the first capacitance and the second capacitance. After the inflow of the electric charge from the photo detecting element into the second capacitance starts, the “current control element” may start delivering the current after a predetermined period has elapsed. The photo detecting apparatus may further include a transistor which determines a level of terminal voltage of the “photo detecting element” and which electrically connects or disconnects the first capacitance and the second capacitance as a result thereof. According to this embodiment, the amount of electric charge may be regulated according to the electric current, so that the dynamic range may be widened while limiting the scale of the circuit.

A drain terminal of the current control element may be connected to the second capacitance, a predetermined fixed potential may be applied to a source terminal thereof, and the current control element may be formed by a P-channel transistor where the gate terminal and the drain terminal are diode-connected. The source terminal of the current control element may be connected to the second capacitance, a predetermined fixed potential is applied to the drain terminal thereof, and the current control element may be formed by an N-channel transistor where the gate terminal and the source terminal are diode-connected. The “predetermined fixed potential” may be a supply voltage. According to this arrangement, a simple structure makes it possible to send a current that cancels part of the electric charge overflowing from the first capacitance.

The current control element may be formed by a transistor, and the current control element may be such that a current by which to cancel part of an electric charge overflowing from the first capacitance is controlled by controlling the gate voltage of the transistor. The current that cancels part of the electric charge overflowing from the first capacitance may be increased in stages by changing the gate voltage in stages. Such an arrangement allows a more flexible adjustment of the amount of electric charge in correspondence to the current.

The photo detecting apparatus may further comprise: a current monitoring circuit which monitors a current delivered by the current control element wherein the current monitoring circuit is provided with a dummy capacitance and a dummy transistor corresponding respectively to the second capacitance and the current control element; and a correction circuit which removes a signal component read out by the current monitoring circuit, from a signal read out from the detection circuit. Such a configuration makes it possible to remove with accuracy the current sent to adjust the amount of electric charge. In particular, when the current is changed in stages, it is possible to reduce nonlinearity resulting from deviation from the design values between the different levels of current.

It is to be noted that any arbitrary combination of the above-described structural components and expressions replaced among a method, an apparatus, a system and so forth are all effective as and encompassed by the present embodiments.

A detailed description will be given hereinbelow of embodiments of the present invention. A photo detecting apparatus according to an embodiment of the present invention is a CMOS image sensor which has a plurality of pixel circuits disposed in m rows and n columns therein.

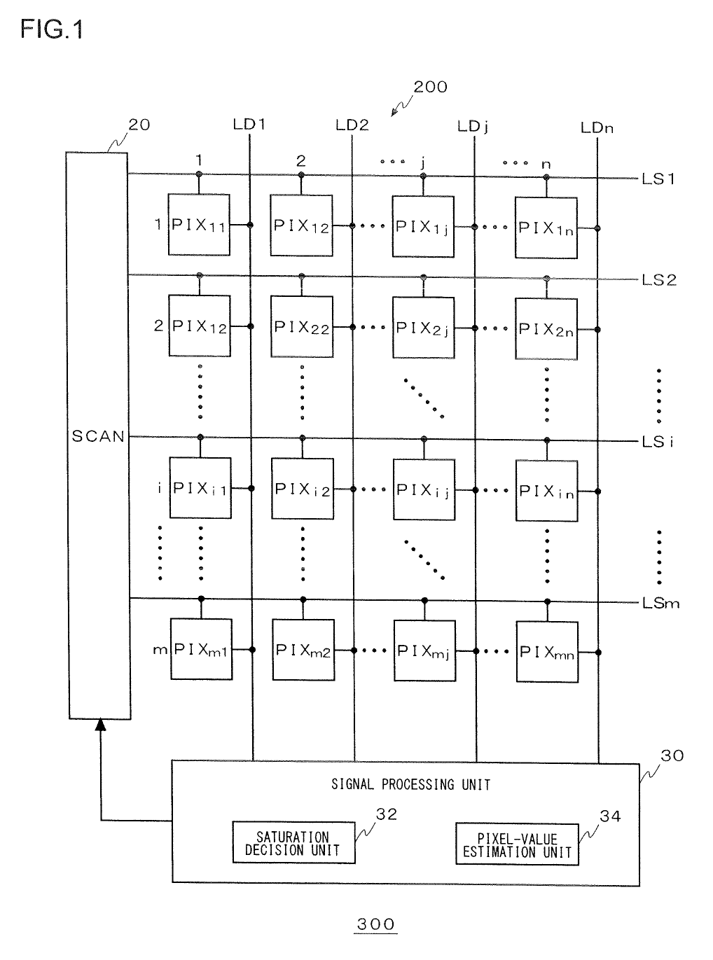

FIG. 1 is a circuit diagram showing an entire structure of an photo detecting apparatus according to the present embodiment. A photo detecting apparatus 300 includes a pixel area 200 having a plurality of pixel circuits (hereinafter referred to simply as “pixels” also) PIX disposed two-dimensionally in m rows and n columns (m, n being an integer greater than or equal to 2), m scanning lines LS1 to LSm (collectively referred to as “scanning line LS”) provided for each row of pixel circuits, n data line LD1 to LDn (collectively referred to as “data line LD”) provided for each column of pixel circuits, a scanning control unit 20, and a signal processing unit 30.

The pixel circuits PIX are each disposed at each of the intersections of a plurality of first data lines LD and a plurality of scanning lines LS. The pixel circuits PIX have each a photodiode, which is a photo detecting element. A pixel circuit PIX outputs the amount of light received by the photodiode as an electric signal to the data line LD.

To distinguish a plurality of pixel circuits PIX, disposed in a matrix, from one another, the pixel at the intersection of an ith row and a jth column is denoted by PIXij. Each pixel circuit PIX, which has the same structure, is of an active pixel structure provided with an active element that amplifies a signal by controlling the voltage applied to the photodiode.

The n data lines LD1 to LDn are provided for their respective columns, and pixels PIX1j to PIXmj of the jth column are connected to the data line LVDj of the jth column. The amount of light detected by each pixel is outputted to the data line LD connected to each pixel. The m scanning lines LS1 to LSm are provided for their respective rows.

The scanning control unit 20 controls the on and off of the active elements contained in the pixel circuits PIX via the scanning lines LS. Though the scanning line LS in each row is shown as a single scanning line in FIG. 1, the actual number of scanning lines is equivalent to the number of active elements to be controlled. The scanning control unit 20 selects the rows successively from the first to the mth row, turns the pixel circuits PIX in the selected row active, and reads out the amounts of light having entered the pixel circuits PIX on the selected row successively. Also, each pixel circuit PIX is supplied with a power supply voltage Vdd by a not-shown power supply line LVdd.

The signal processing unit 30 processes the output signal of each pixel circuit PIX acquired via the data line LD. The signal processing unit 30 is provided with a saturation decision unit 32 and a pixel-value estimation unit 34. The saturation decision unit 32 determines whether a stored charge amount of each pixel circuit PIX is saturated or not. If the stored charge amount of the each pixel circuit PIX is saturated, the pixel-value estimation unit 34 will estimate an output value of the saturating pixel circuit PIX, from an output value of a nonsaturated pixel circuit PIX disposed adjacent to the saturated pixel circuit PIX. A general interpolation operation may be used as a method for estimating the output value.

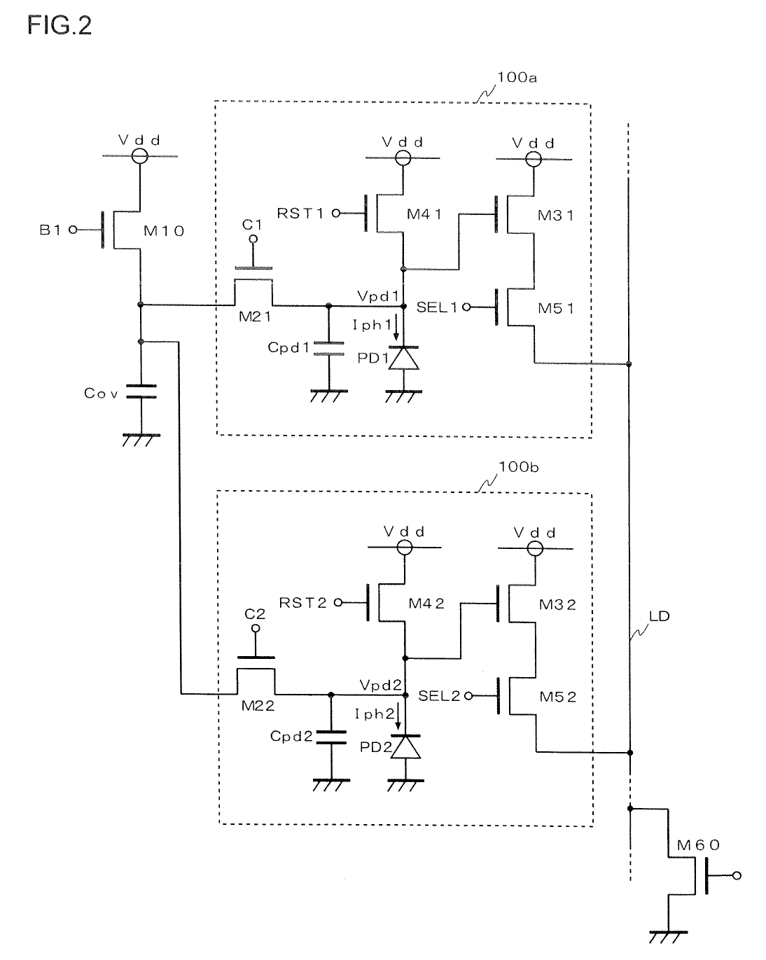

FIG. 2 is a circuit diagram showing a structure of a pixel circuit that constitutes a photo detecting apparatus according to an embodiment of the present invention. FIG. 2 shows two adjacent pixel circuits 100a and 100b where a data line is shared by them. Hereinafter, these two pixel circuits 100a and 100b are generically referred to as “pixel circuit 100” also. The first pixel circuit 100a includes a photo diode PD1, a reset transistor M41, an amplifier transistor M31, a selection transistor M51, and an overflow drain transistor M21. The second pixel circuit 100b also includes a photo diode PD2, a reset transistor M42, an amplifier transistor M32, a selection transistor M52, and an overflow drain transistor M22. A load transistor M60 is provided externally to the pixel circuit 100. The load transistor M60 functions as a constant current source. A drain terminal of the load transistor M60 is connected to the data line LD; a source terminal thereof is connected to ground voltage GND; and a predetermined bias voltage is applied to a gate terminal thereof. A pixel signal is read out from the drain terminal of the load transistor M60. The structure of the first pixel circuit 100a is identical to that of the second pixel circuit 100b. Thus, a description is given hereunder of the first pixel circuit 100a only and that of the second pixel circuit 100b is omitted.

In the first pixel circuit 100a, a parasitic capacitance of the photodiode PD1 itself, interwiring capacitance or the like exists in a cathode terminal of the photo diode PD1. Hereinafter this capacitance will be referred to as “cathode capacitance Cpd1”. The reset transistor M41, the amplifier transistor M31, the selection transistor M51 and the overflow drain transistor M21 are all N-channel MOSFETs (Metal Oxide Semiconductor Field Effect Transistors). The reset transistor M41 and the photo diode PD1 are connected in series between supply voltage Vdd and ground voltage GND. A source terminal of the reset transistor M41 is connected to the photo diode PID, and the supply voltage Vdd is applied to a drain terminal thereof. A reset signal RST1 is inputted to a gate terminal of the reset transistor M41.

The cathode terminal of the photodiode PD1, which is connected to the reset transistor M41, is connected to a gate terminal of the amplifier transistor M31. In the amplifier transistor M31, the supply voltage Vdd is applied to a drain terminal of the amplifier transistor M31, and a source terminal thereof is connected to a drain terminal of the selection transistor M51. When the selection transistor M51 turns on, the source terminal of the amplifier transistor M31 conducts to the drain terminal of the load transistor M60, so that the amplifier transistor M31 functions as a source follower. A source terminal of the selection transistor M51 is connected to a data line LD, which is provided to each of the columns of the CMOS image sensor. The amplifier transistor M31 and the selection transistor M51 function as a detection circuit for detecting a voltage in proportion to the amount of light received by the photodiode PD1. A source terminal of the overflow drain transistor M21 is connected to the cathode terminal of the photo diode PD1, whereas a drain terminal of the overflow drain transistor M21 is connected to one end of an overflow drain capacitor Cov which will be described later. A control signal C1 is inputted to a gate terminal of the overflow drain transistor M21.

A basic operation of the first pixel circuit 100a will now be explained. As the reset signal RST1 inputted to the gate terminal of the reset transistor M41 goes high, the reset transistor M41 turns on, the supply voltage Vdd is applied to the photodiode PD1, and the cathode terminal thereof is charged by the supply voltage Vdd. Next the reset transistor M41 is turned off. In this state, as light hits the photodiode PD1, a photocurrent Iph1 flows, and the electric charge stored in the cathode capacitance Cpd1 of the photodiode PD1 is discharged. At this time, the voltage at the cathode terminal of the photodiode PD1 changes in relation to the light intensity and the charge storage time. The amplifier transistor M31 outputs the voltage at the cathode terminal of the photodiode PD1. Now, after the passage of a predetermined storage time, having a selection signal SEL1 go high will turn on the selection transistor M51 and have a voltage in proportion to the amount of light received by the photodiode PD1 outputted to the data line LD, and thus the amount of light received by each pixel circuit can be detected by an external circuit.

In addition to the pixel circuit 100 according to the present embodiment, the photo detecting apparatus 300 includes the overflow drain capacitor Cov. A current supply transistor M10 and the overflow drain capacitor Cov are connected in series between the supply voltage Vdd and the ground voltage GND. The overflow drain capacitor Cov is provided between a source terminal of the current supply transistor M10 and the ground voltage GND. The overflow drain capacitor Cov stores the charge overflowing from the photodiode PD1 while the overflow drain transistor M21 of the first pixel circuit 100a is conducting. Alternatively, the overflow drain capacitor Cov stores the charge overflowing from the photodiode PD2 while the overflow drain transistor M22 of the second pixel circuit 100b is conducting. The current supply transistor M10 is an N-channel MOSFET; and the supply voltage is applied to a drain terminal thereof, whereas a predetermined bias voltage B1 is applied to a gate thereof. The source terminal of the current supply transistor M10 is connected to one end of the overflow drain capacitor Cov, and supplies a predetermined current to the overflow drain capacitor Cov. By supplying this current to the overflow drain capacitor Cov, the saturated electric charge is prevented from being mixed into adjacent pixels from the overflow drain capacitor Cov.

Although the current supply transistor M10 and the overflow drain capacitor Cov are provided outside the pixel circuit 100, these may be provided within the first pixel circuit 100a or the second pixel circuit 100b. They may also be provided across the first pixel circuit 100a and the second pixel circuit 10b. In the case of FIG. 2, the current supply transistor 10 and the overflow capacitor Cov are shared by two pixel circuits 100 but may be shared by three or more pixel circuits.

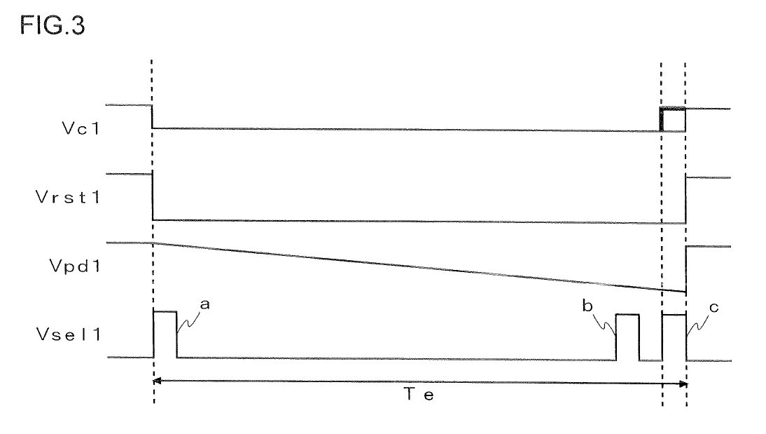

FIG. 3 is an operational sequence diagram of each pixel circuit 100. FIG. 3 shows a gate voltage Vc1 of the overflow drain transistor M21, a gate voltage Vrst1 of the reset transistor M41, a cathode voltage Vpd1 of the photodiode PD1, and a gate voltage Vsel1 of the selector transistor M51. In the initial state, the overflow drain transistor M21 and the reset transistor M41 are on, and the selector transistor M51 is off. The cathode voltage Vpd1 of the photodiode PD1 is maintained at supply voltage Vdd.

To read out a reset level, a high-level signal a is inputted to the gate terminal of the selector transistor M51 so as to turn on the selector transistor M51 temporarily. Simultaneously with that, an exposure period Te starts, and an intermediate voltage, which is a predetermined bias voltage, is applied to the gate terminal of the overflow drain transistor M21. This creates a state in which the charges overflowing from the cathode capacitance Cpd1 can be stored in the overflow drain capacitor Cov. Now, when a low-level signal is inputted to the gate terminal of the reset transistor M41, the reset transistor M41 turns off. After the start of the exposure period Te, the photodiode PD1 keeps storing electric charges according to the amount of light received, and the cathode voltage Vpd drops gradually.

When a preset period of time has elapsed from the start of the exposure period Te, a high-level signal b is inputted to the gate terminal of the selector transistor M51, so that the selector transistor M51 turns on temporarily. A not-shown level deciding circuit connected to the data line LD detects the cathode voltage Vpd1 at the photodiode PD1. The voltage thus detected is used to predict whether an electric charge will be stored in the overflow drain capacitor Cov before the start of the next signal reading period or not. A designer may use an experiment or simulation to obtain a threshold voltage which is to be compared with the detected voltage.

Where the detected voltage indicates that an electric charge is stored in the overflow drain capacitor Cov or it predicts that an electric charge will be stored before the start of a signal reading period, the level deciding circuit inputs a high-level signal (indicated in a bold line in FIG. 2) to the overflow drain transistor M21, thereby turning the overflow drain transistor M21 on. This makes it possible to read out a signal based on both the combined charge stored in the cathode capacitance Cpd and the overflow drain capacitor Cov, during the signal reading period.

On the other hand, where the detected voltage indicates that electric charge is not stored in the overflow drain capacitor Cov and besides it predicts that the electric charge will not be stored before the start of a signal reading period, the level deciding circuit maintains the gate voltage of the overflow drain transistor M2 at the value of intermediate voltage. Otherwise, the level deciding circuit may turn off the overflow drain transistor M21 completely by inputting a low-level signal to the gate terminal thereof. This makes it possible to read out a signal based on the charge stored in the cathode capacitance Cpd1 only, during the signal reading period.

Prior to the end of the exposure period Te, a high-level signal c for detecting the cathode voltage Vpd1 of the photodiode PD1 is inputted to the gate terminal of the selector transistor M51, so that the selector transistor M51 turns on temporarily. A signal, which is the cathode voltage Vpd at this time amplified by the amplifier transistor M3, is read out to the data line LD.

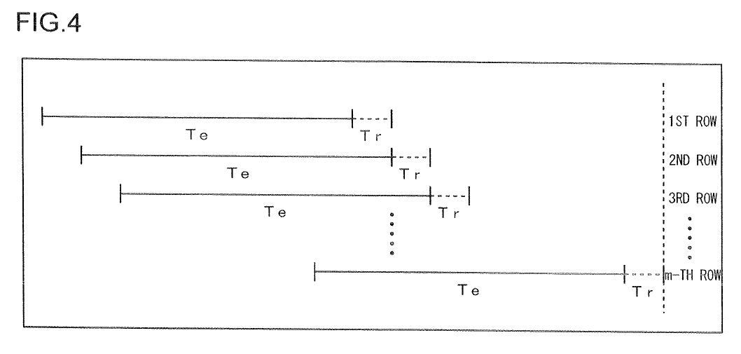

FIG. 4 illustrates a first operation example of the photo detecting apparatus 300. The first operation example shows a case where the overflow drain capacitor Cov is not shared. Though in FIG. 2 a single overflow capacitor Cov is shared by two pixel circuits 100, a structure is possible where the overflow drain capacitor Cov is used exclusively for a particular pixel circuit 100. That is, there are provided a pixel circuit 100 connected with the overflow drain capacitor Cov and a pixel circuit 100 which is not connected therewith. For example, in FIG. 2, the first pixel circuit 100a is connected to the overflow drain capacitor Cov whereas the second pixel circuit 100b is not connected to the overflow drain capacitor Cov. That is, a structure where the second pixel circuit 100b is not connected thereto may be such that the overflow drain capacitors Cov is connected to a half of the pixel circuits 100 in all the pixel circuits 100 while the overflow drain capacitor is not connected to the remaining half of the pixel circuits 100. In a case where a processing for switching the pixel circuits 100, as will be described later, using the overflow drain capacitors Cov in units of frame.

Hereinbelow, the first operation example will be described in detail by referring to FIG. 1 and FIG. 4. The scanning control unit 20 controls the first-row scanning line LS1 among a plurality of pixel circuits 100 which are arranged two-dimensionally in m rows and n columns, so as to have the exposure period Te of the first-row pixel circuit 100 started. When the exposure period Te ends, the scanning control unit 20 has a reading period Tr started. Since the first-row pixel circuit 100 and the second-row and subsequent pixel circuits 100 use the data line LD in common, it is required that there shall be no overlapping period between the reading period Tr of the first-row pixel circuit 100 and the second-row and subsequent pixel circuits 100. Thus, the scanning control unit 20 has an exposure time Te of the second-row pixel circuit 100 started by delaying it by at least the reading period Tr of the first-row pixel 100 after the exposure period Te of the first-row pixel circuit 100 has started. Similarly, for the third-row and the subsequent rows, the scanning control unit 20 has an exposure time Te started by delaying it by at least a reading period Tr of a previous-row pixel 100 after the exposure period Te of the previous-row pixel circuit 100 has started.

Next, a second operation example will be described. In the second operation example, a pixel circuit 100 that uses the overflow drain capacitor Cov and a pixel circuit 100 that does not use the overflow drain capacitor Cov are switched therebetween in units of frame. The pixel circuit 100 using the overflow drain capacitor Cov and the pixel circuit 100 not using it are fixed in the same frame.

For example, in a case when the overflow drain capacitor Cov is used in the two pixel circuits 100 as shown in FIG. 2, the pixel circuit 100 using it which is the first pixel circuit 10a, for example, operates as shown in FIG. 3 while the overflow drain transistor M22 in the pixel circuit 100 not using it which is the second pixel circuit 10b, for example, operates differently. That is, during an exposure period Te, the gate voltage of the overflow drain transistor M22 maintains a ground level or a negative voltage while the overflow drain transistor M22 maintains an OFF state. Accordingly, the inflow of electric charge into the overflow drain capacitor Cov from the second pixel circuit 100b that does not use the overflow drain capacitor Cov is prevented.

The scanning control unit 20 switches, in units of frame, the pixel circuit 100 using the overflow drain capacitor Cov and the pixel circuit 100 not using it by controlling the gate voltages of the overflow drain transistors M21 and M22. The switching may be done for each frame or for every few frames. The exposure and the readout timing in the second operation example are the same as those in the first operation shown in FIG. 4.

In a case where an interlace image-pickup is employed, it is preferred that the pixel circuit 100 using the overflow drain capacitor Cov be assigned to a row selected in a certain frame and the pixel circuit 100 not using it be assigned to a row which is not selected. In this case, in comparison with a structure where the overflow drain capacitors Cov are provided for all of the pixel circuits, the circuit area can be reduced while the exposure time and the dynamic range are kept at the same level.

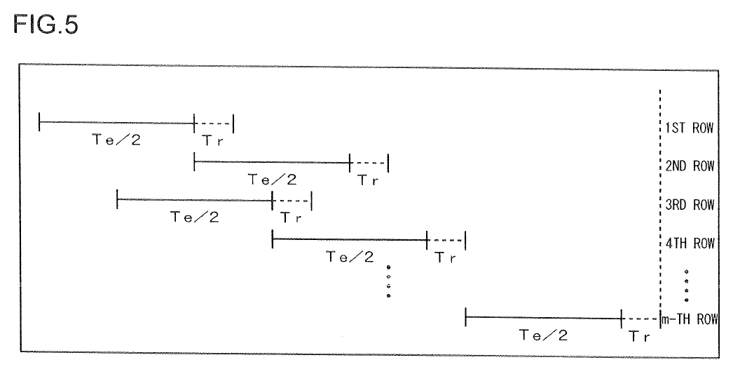

FIG. 5 illustrates a third operation example of the photo detecting apparatus 300. The third operation example shows a case where the overflow drain capacitor Cov is shared by two vertical pixels where the data line LD is commonly used by them, as shown in FIG. 2. However, no switching processing as in the second operation example controlled by the overflow drain transistors M21 and M22 is performed in this third operation example. Instead, the exposure periods Te of the pixel circuits 100 sharing the overflow drain capacitor Cov are not overlapped with each other.

In a case when the overflow drain capacitor Cov, which is electrically connected with a plurality of pixel circuits 100, is shared thereby and the exposure periods overlap with each other in the same frame in these pixel circuits 100, a high-intensity light entering these pixel circuits 100 causes the commonly used overflow drain capacitor Cov to be charged with electric charge. This results in mixture of image signals. Conversely, if the exposure periods do not overlap, the overflow drain capacitor Cov can be shared without invoking the above-described switching processing.

In FIG. 5, the scanning control unit 20 has an exposure period Te of the first-row pixel 100 started by controlling the first-row scanning line LS1 in a plurality of pixel circuits 100 arranged in m rows and n columns. The exposure period Te/2 in the third operation example is a half of the exposure period Te in the first operation example. Thereby, an arrangement can be so made that the exposure periods Te/2 do not overlap between the two pixel circuits 100 sharing an overflow drain capacitor Cov. When an exposure period Te/2 ends, the scanning control unit 20 has a reading period Tr started. Upon this, an exposure period Te/2 of the second-row pixel circuit 100 sharing the overflow drain capacitor Cov is started.

As described above, since a pixel circuit 100 of each row shares the data line LD with a pixel circuit 100 of another row, it is required that a reading period Tr of a pixel circuit 100 shall not be overlapped with that of another pixel circuit 100 within the reading operation of one frame. When the exposure period Te of the first-row pixel circuit 100 starts, the scanning control unit 20 has an exposure period Te/2 of a third-row pixel circuit 100, which does not share the overflow drain capacitor Cov, started after a predetermined period has elapsed. Here, the exposure period Te/2 of the third-row pixel circuit 100 needs to be started so that the reading period Tr of the first-row pixel circuit does not overlap with the reading period Tr of the third-row pixel circuit 100. Exposure periods Te/2 of a fourth row and the subsequent rows will be started using the same rule as described above.

For the case where the overflow drain capacitor Cov is shared by three or more pixel circuits 100 or is shared by pixel circuits 100 located apart from each other, the exposure period Te/2 and the reading period Tr are started by the same rule. That is, the start timing of the exposure period Te/2 and the reading period Tr of each row of a pixel circuit 100 are set so that the exposure periods Te/2 do not overlap between the pixel circuits 100 that share an overflow drain capacitor Cov and the reading periods Tr do not overlap in all rows of the pixel circuits 100.

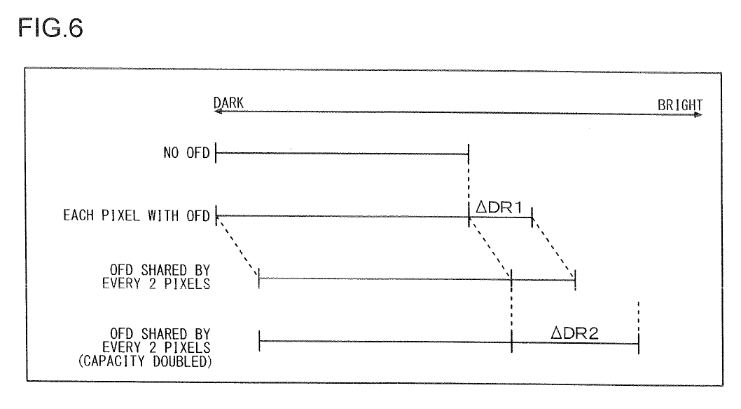

FIG. 6 illustrates the size of a dynamic range in each structure of the photo detecting apparatus 300 and a result of comparison among them. In FIG. 6, the dynamic range listed on the top is the dynamic range of a general photo detecting apparatus without the overflow drain capacitor Cov. Hereinbelow, this range is taken as a reference, and the dynamic ranges are compared among those of the other structures. The second dynamic range represents a case where the overflow drain capacitors Cov are provided in all of the pixel circuits 100. The provision of the overflow drain capacitor Cov increases the stored charge amount. Hence, the dynamic ranges is widened in a brighter direction. That is, the overflow drain capacitor Cov will not saturate easily for the high-intensity light.

In a case where the overflow drain capacitors Cov are connected to a half of pixels as shown in the first operation example and the second operation example, the dynamic range thereof will be the same. Since a saturated pixel is calculated principally from a pixel which is not connected to an overflow drain capacitor Cov, the dynamic range in this case is the same as that in a case where the overflow drain capacitors Cov are connected to all of the pixels. However, the resolution of a part including the saturated pixel is lower than the above-described structure.

A third dynamic range is one obtained by employing a structure where the overflow drain capacitor Cov is shared by two pixels as shown in the third operation example. As described above, if the exposure period is made short and the overflow drain capacitor Cov is shared, the sensitivity drops as much as that corresponding to the shortened exposure period. However, the dynamic range shifts to a bright direction and the size itself remains unchanged. This is because the increase ΔDR1 in dynamic range as a result of the provision of the overflow drain capacitor Cov is the same.

A fourth dynamic range is one obtained by employing a structure where the area of the overflow drain capacitor Cov mounted on a photo detecting apparatus having the above-described third dynamic range is doubled. With the area of the overflow drain capacitor Cov doubled, the increase ΔDR2 in dynamic range is also doubled. Thus, the fourth dynamic range is widened in a bright direction as compared with the third dynamic range.

According to the present embodiment structured as above, of all of the pixel circuits 100 there are provided the pixel circuits 100 using the overflow drain capacitors Cov and also the pixel circuits 100 not using the overflow drain capacitor Cov. As a result, the dynamic range can be widened while the circuit scale is suppressed. That is, compared with a structure where the overflow drain capacitors Cov are connected respectively to all of the pixel circuits 100, the total area occupied by the overflow drain capacitors Cov can be reduced and therefore the total area of the photo detecting apparatus 300 can also be reduced. The values of saturated pixel circuits 100 are estimated from the values of the surrounding pixels, so that the dynamic range can be kept the same way as with the above-described structure.

In particular, by employing the first operation example, the pixel circuits 100 using the overflow drain capacitor Cov and the pixel circuits 100 not using the overflow drain capacitor Cov are constantly fixed. Hence, the wiring therefor can be simplified.

By employing the second operation example, the pixel circuit 100 using the overflow drain capacitor Cov and the pixel circuit 100 not using the overflow drain capacitor Cov are switched frame by frame. Thus, the drop in resolution which may be caused in picking up moving images with little movement can be suppressed and therefore the visibility can be improved. That is, if the strong light entering the pixel circuits 100 not using the overflow drain capacitors Cov continues, the values of said pixel circuits 100 will continue to be estimated based on the pixel signals of the surrounding pixel circuits 100. This state can be prevented by the above-described switching processing.

As advantageous effect commonly achieved by the first operation example and the second operation example, the exposure period can be secured and therefore darker images can be dealt with. Also, the reduction in resolution due to the fact that a pixel circuit 100 not using the overflow drain capacitor Cov has reached saturation is likely to occur only in areas where the high-intensity light, such as headlight of a car being driven at night, enters, thus giving little impact on the visibility. This is because not so high resolution is required for such areas.

By employing the third operation example, the exposure period is shortened, so that the sensitivity to bright light can be improved. Also, even if the total area of the overflow drain capacitor Cov is increased to as much as the total size in which the overflow drain capacitors Cov are provided in all of the pixel circuits, the dynamic range in the third operation example can still be expanded while the circuit scale is about the same.

Next, a description will be given of an example where the present embodiment is applied to a case where color images are picked up using a color filter.

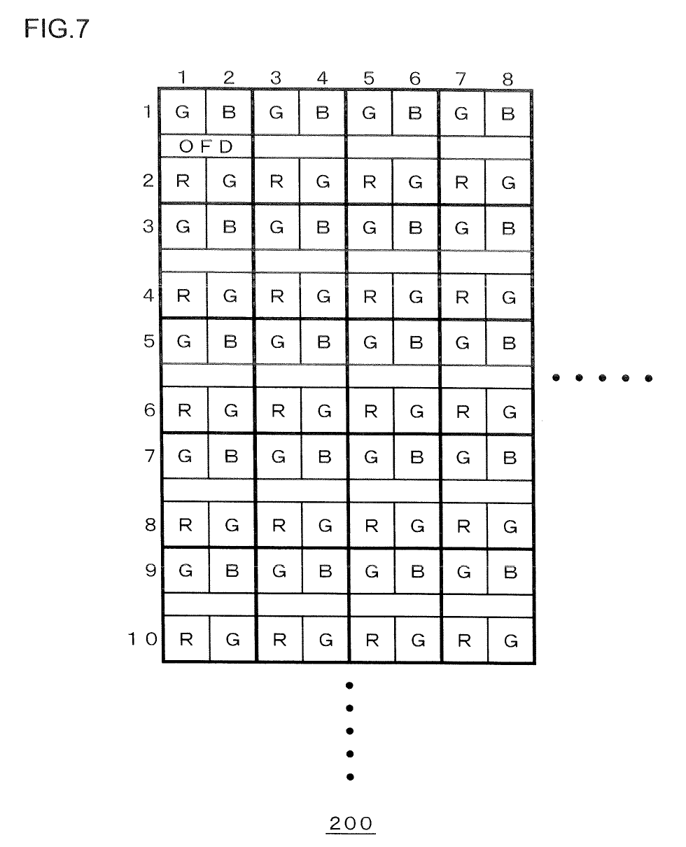

FIG. 7 illustrates an image pickup area 200 generated by a Bayer arrangement. The minimum unit of the Bayer arrangement is constituted by 4 pixels. Pixels having color filters of green G are arranged on a diagonal. Pixels having color filter of red R and blue B are arranged on other pixels. According to the present embodiment, an area on which an overflow drain capacitor Cov (hereinafter referred to as “OFD area” also) is formed is provided between the upper two-row pixels and the lower two-row pixels that constitute the minimum unit of the Bayer arrangement.

If in this manner the photo detecting apparatus 300 having the image pickup area 200 operates according to the second operation example, the scanning control unit 20 will need to select rows using the overflow drain capacitor Cov in such a manner as to maintain the ratio of red R, green G and blue B in each frame. For example, the first row, the fourth row, the fifth row, the eighth row, the ninth row, are selected as rows capable of storing the electric charge in a certain frame of FIG. 7. Thus, the second row, the third row, the sixth row, the seventh row, the tenth row . . . do not use the overflow drain capacitor Cov. Also, the second row, the third row, the sixth row, the seventh row, the tenth row . . . are selected as rows capable of storing the electric charge in another frame.

By performing the switching as described above, the ratio of green G, blue B and red R can be set to 2:1:1 in every frame. Thereby, the case where the pixel circuit 100 of a particular color saturates to disrupt the color balance can be prevented from happening.

A description has been given above of a case where the sum of green G pixels is made equal to the sum of blue B pixels and red R pixels. In this regard, the sum of green G pixels may be set larger than that of blue B pixels and red R pixels. For example, this can be achieved by designing in such a manner that two green G pixels are always selected even when the frame is switched in the minimum unit of a certain Bayer arrangement. By employing this scheme, since the spectral sensitivity of human eyes is set close the green color as a peak, the reduction in resolution of green color is not easily recognized in a bright area and therefore the apparent resolution can be improved. In the above, a description has been given of an example where when the green G, blue B and red R are Bayer arranged, the color ratio is maintained even though the frame is switched. In this regard, the present embodiment is applicable to the arrangements other the Bayer arrangement. Also, the present embodiment is applicable to color images using complementary colors, such as cyan, magenta, yellow and green, and other colors.

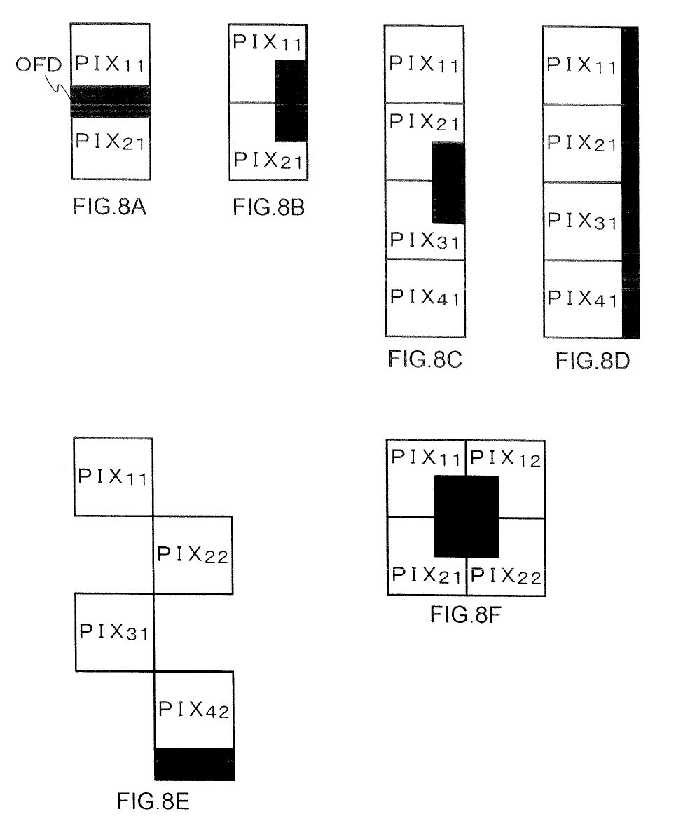

FIGS. 8A to 8F illustrate examples of arrangement where an overflow drain capacitor Cov is shared. Note that patterns of OFD areas shown in FIGS. 8A to 8F do not limit the material used. FIGS. 8A and 8B illustrate examples where the overflow drain capacitor Cov is shared by two vertically adjacent pixels PIX₁₁ and PIX₂₁, and an OFD area is formed on part of two adjacent pixels PIX₁₁ and PIX₂₁. In FIG. 8A, the OFD area is formed along a common side of two adjacent pixels PIX₁₁ and PIX₂₁. The OFD area is formed on each of pixel areas in a manner that an approximately half of the OFD area lie on each side thereof. In FIG. 8B, the OFD area is formed along the vertical sides of two vertically arranged pixels PIX₁₁ and PIX₂₁. The OFD area is formed on each of pixel areas in a manner that an approximately half of the OFD area lies on each side thereof.

FIGS. 8C to 8F illustrate examples of arrangement where an overflow drain capacitor Cov is shared by neighboring four pixels. In FIGS. 8C and 8D, the overflow drain capacitor Cov is shared by a group of pixels composed of four pixels PIX₁₁, PIX₂₁, PIX₃₁ and PIX₄₁ which are vertically arranged in series. In FIG. 8C, the OFD area is formed along part of a common side of two adjacent pixels which are the second pixel PIX₂₁ and the third pixel PIX₃₁. The OFD area is formed on each of pixel areas in a manner that an approximately half of the OFD area lie on each side thereof. In FIG. 8D, the OFD area is formed along the sides of a group of pixels composed of four pixels PIX₁₁, PIX₂₁, PIX₃₁ and PIX₄₁ which are vertically arranged in series. The OFD area is formed external to each of pixel areas.

In the case of FIG. 8E, an overflow drain capacitor Cov is shared by a group of pixels composed of four pixels PIX₁₁, PIX₂₂, PIX₃₁ and PIX₄₂. These four pixels PIX₁₁, PIX₂₂, PIX₃₁ and PIX₄₂ are vertically and alternately arranged, as in a checker pattern, so that PIX₂₂ and PIX₄₂ are shifted to the right of PIX₁₁ and PIX₃₁ by one pixel, respectively. An OFD area is formed on the base of the bottommost pixel PIX₄₂. In the case of FIG. 8F, an overflow drain capacitor Cov is shared by a group of pixels composed of four pixels PIX₁₁, PIX₂₁, PIX₁₂ and PIX₂₂ placed in 2-by-2 square. An OFD area is formed in a center area of the group of pixels. The OFD area is formed on each of pixel areas in a manner that an approximately quarter of the OFD area lies on each area.

As shown in FIGS. 8A to 8F, one overflow drain capacitor Cov can be shared by a group of pixels constituted by a plurality of pixels in the vertical, horizontal and diagonal directions or an arbitrary combination thereof. In particular, the structure except for that of FIG. 8E is such that a distance from each pixel constituting a plurality of pixels to the OFD area is practically equal. When the distance is made practically equal, the wiring length and the like are each equal. This can prevent the variation in characteristics due to the wiring resistance and the like. Also, the OFD area provided outside the pixel area can be shared by a group of pixels arranged in a checker patter, as shown in FIG. 8E. Thus, a designer can freely lay out the structure in consideration of the wiring of other elements or manufacturing process.

The present invention has been described based on embodiments. The above-described embodiments are merely exemplary, and it is understood by those skilled in the art that various modifications to the combination of each component and each process thereof are possible and that such modifications are also within the scope of the present invention.

In the above-described embodiments, the current supply transistor M10 basically supplies the constant current to the overflow drain capacitor Cov. In contrast thereto, the current supplied to the overflow drain capacitor Cov is varied in a modification. As a result, the charge amount stored in the overflow drain capacitor Cov is adjusted.

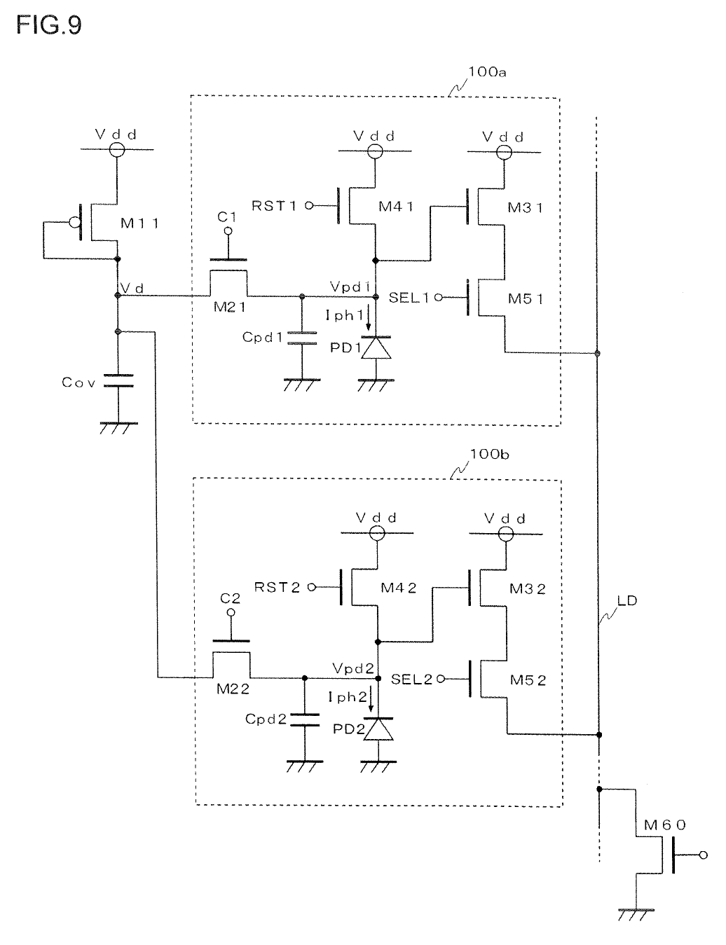

FIG. 9 is a circuit diagram showing a structure of an image circuit according to a first modification. The structure of this pixel circuit is basically the same as that shown in FIG. 2. Hereinbelow, the differences will be described. In a first modification, a current control transistor M11 is provided in place of the current supply transistor M10. The current control transistor M11 is a P-channel MOSFET and the supply voltage Vdd is applied to a source terminal thereof. A drain terminal of the current control transistor M11 is connected to one end of the overflow drain capacitor Cov. The gate terminal and the drain terminal of the current control transistor M11 are diode-connected with each other. The first pixel circuit 100a and the second pixel circuit 100b can selectively use the overflow drain capacitor Cov by controlling the on an off of the overflow drain transistor M21 and the overflow drain transistor M22.

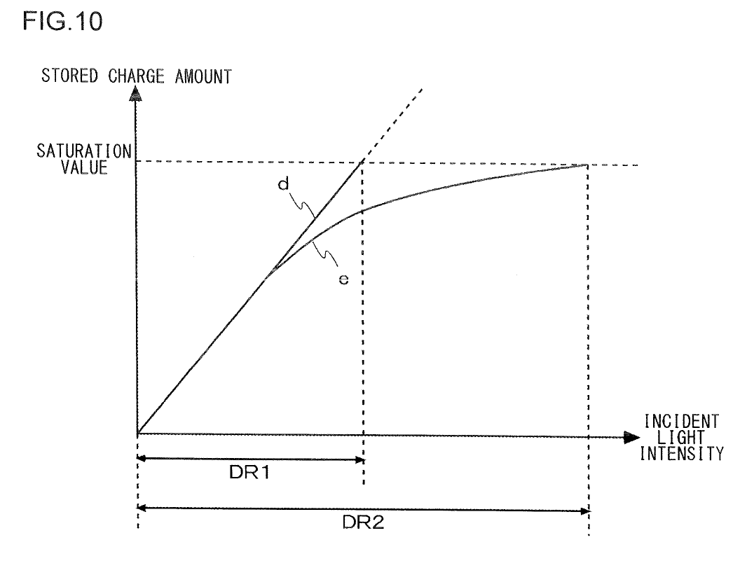

FIG. 10 is a diagram showing a relationship between incident light intensity and stored charge amount at the overflow drain capacitor Cov according to the first modification. A description is given hereunder of the first pixel circuit 10a as an example. The cathode voltage Vpd1 drops in proportion to the intensity of light incident on the photodiode PD1. Along with that, the overflow drain transistor M21 turns on, and the drain voltage of the current control transistor M11 also drops. Since the gate terminal and the drain terminal of the current control transistor M11 are diode-connected, the relationship between the incident light intensity and the stored charge amount is linear in the beginning but halfway begins changing in a quadratic-curve manner as represented by a characteristic e shown in FIG. 10. This is because when the intensity of light reaches a certain level, the drain voltage Vd drops, the current control transistor M11 turns gradually on, and thus current I flows. With the drain voltage Vd further dropping, it is possible to allow even larger current I to flow. It should be noted that the characteristic curve defining the relationship between incident light intensity and stored charge amount can be designed arbitrarily by adjusting the characteristics, such as gate length or gate width, of the current control transistor M11.

In this arrangement, the amount of charge stored in the cathode capacitance Cpd1 and the overflow drain capacitor Cov is (Iph−I)t, so that the larger the current I that is allowed to flow, the less the stored charge amount of the overflow drain capacitor Cov will be. Here Iph1 is a photocurrent flowing through the photodiode PD1, I a current that is caused to flow by the current control transistor M11, and t a storage time. In this manner, the current caused to flow by the current control transistor M11 acts as a current that cancels the photocurrent flowing through the photodiode PD1. This current control transistor M11 works on the side of the overflow drain capacitor Cov only, so that widening the dynamic range on the higher illuminance side by sending the current I will have no influence on the readout characteristics at the lower illuminance. It should be understood here that in order to obtain an actual amount of light received, the current flowing through the current control transistor M11 needs to be removed as an offset component in a subsequent stage. Also, this current may be removed using a dummy pixel circuit 110 and a subtraction circuit 120 which will be discussed later.

In contrast to this, where the current control transistor M11 is not provided or where the current is not allowed to flow despite the presence of the transistor, the relationship between the incident light intensity and the stored charge amount represents a linear response up to the saturation value as indicated by a characteristic d shown in FIG. 10. A dynamic range DR1 in this case will be narrower than a dynamic range DR2 for which the current is delivered by the use of a current control transistor M11.

As described above, according to the first modification, it is possible to adjust the amount of charge to be stored in the overflow drain capacitor Cov by connecting a diode-connected P-channel MOSFET to the terminal of the overflow drain capacitor Cov, which is on the side where the overflow drain capacitor Cov is coupled to the cathode terminals of the photodiode PD1 and PD2. That is, when the voltage at said terminal drops due to a rise in incident light intensity, the amount of current is increased automatically, so that said voltage will drop in a gentler slope. Hence, the above-mentioned terminal voltage will not drop easily for the same intensity of light, which means that the stored charge amount will not saturate easily. As a result, the same dynamic range can be realized by a smaller capacitance. Thus, the first modification can achieve a wider dynamic range while suppressing the increase in circuit area.

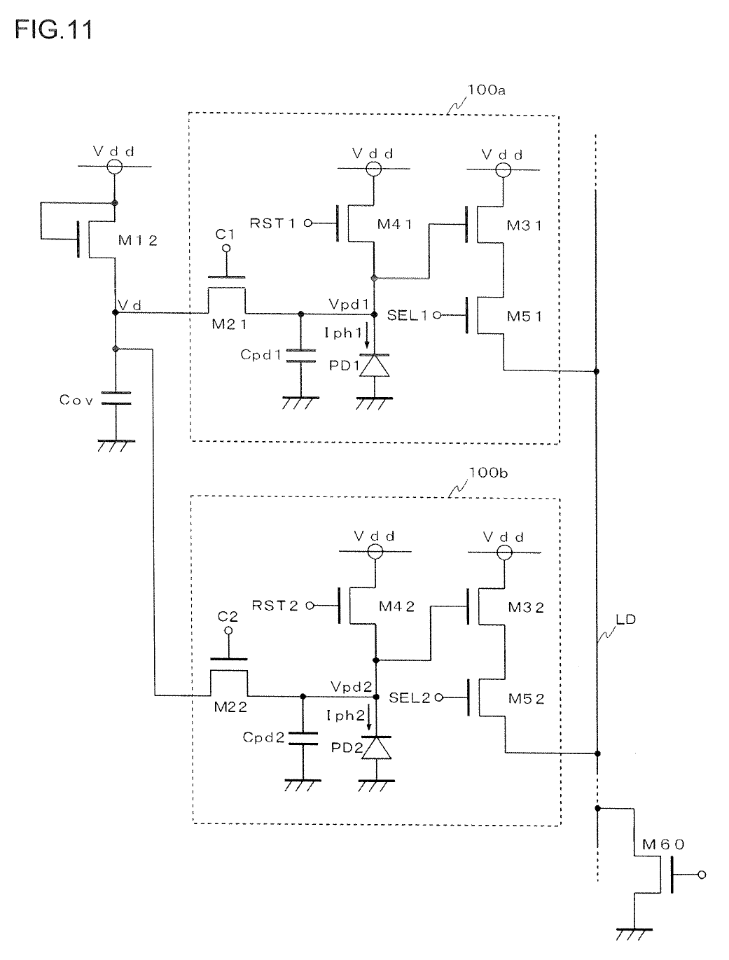

A second modification will now be described. FIG. 11 is a circuit diagram showing a pixel circuit according to the second modification. A pixel circuit according to the second modification uses a current control transistor M12, which is an N-channel MOSFET, instead of the current control transistor M11, which is a P-channel MOSFET, in the pixel circuit according to the first modification. The supply voltage Vdd is applied to a drain terminal of the current control transistor M12, and one end of an overflow drain capacitor Cov is coupled to a source terminal of the current control transistor M12. The gate terminal and the drain terminal of the current control transistor M12 are diode-connected with each other.

The relationship between incident light intensity and stored charge amount at the overflow drain capacitor Cov according to the second modification is the same as one shown in FIG. 10. That is, as the incident light intensity rises, the overflow drain transistor M21 turns on, and the source voltage of the current control transistor M12 drops. Along with this, a gate-source voltage of the current control transistor M12 keeps rising, and the current control transistor M12 turns on gradually, thereby causing current I to flow.

As described above, according to the second modification, the effects similar to those of the first modification is achieved by the use of an N-channel MOSFET.

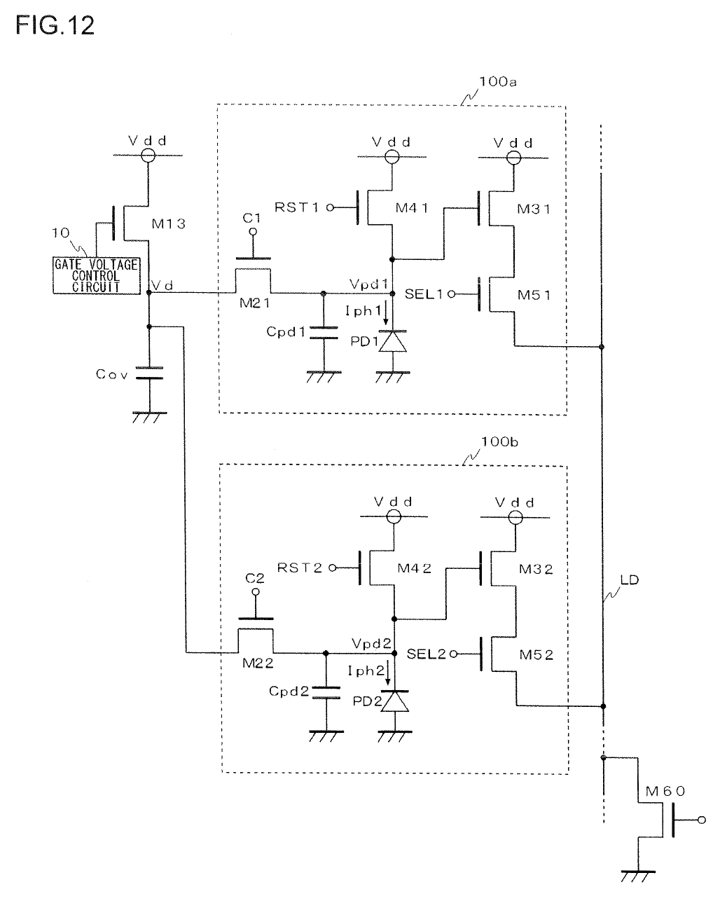

A third modification will now be described. FIG. 12 is a circuit diagram showing a pixel circuit according to a third modification. In the first and second modifications, a characteristic of a diode-connected MOSET is utilized to supply a current to adjust the stored charge amount. In the third modification, on the other hand, a designer may arbitrarily set the timing of delivering the current and the value of the current by controlling the gate voltage to be applied to the gate terminal of the MOSFET.

The pixel circuit according to the third modification includes a gate voltage control circuit 10. The gate voltage control circuit 10 controls a bias voltage to be applied to the gate terminal of the current control transistor M13. The current control transistor M13 may be constructed by either an N-channel MOSFET or a P-channel MOSFET.

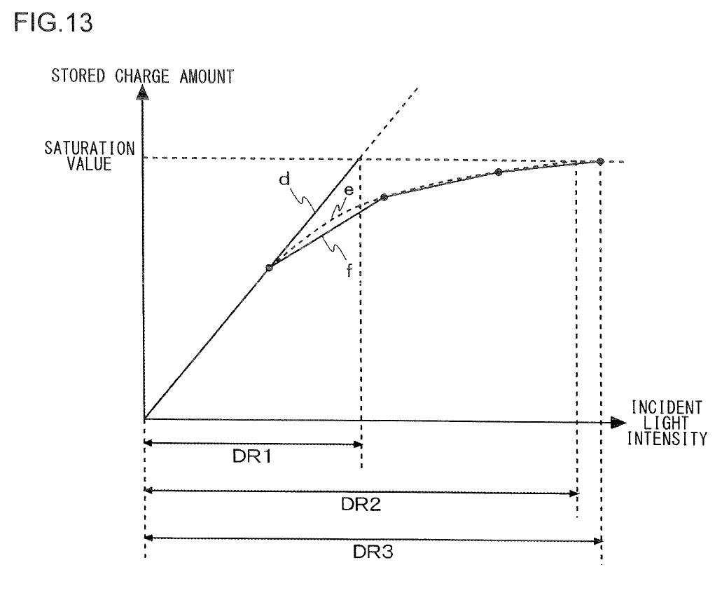

FIG. 13 is a diagram showing a relationship between incident light intensity and stored charge amount at an overflow drain capacitor Cov according to the third modification. The cathode voltage Vpd1 drops in proportion to the intensity of light entering the photodiode PD1. Along with that, the overflow drain transistor M21 turns on, and the source voltage of the current control transistor M13 also drops. The gate voltage control circuit 10 can cause a predetermined amount of current to flow by turning the current control transistor M13 on by raising the gate voltage with predetermined timing.

By allowing a predetermined amount of current to flow, the slope of a characteristic f representing the relationship between the incident light intensity and the stored charge amount in FIG. 13 can be made gentler. By further raising the gate voltage with predetermined timing, the gate voltage control circuit 10 can increase the amount of current and thus make the slope of the characteristic f even gentler. In this manner, the gate voltage control circuit 10 can raise the amount of current in stages by raising the gate voltage in stages. Depending on the setting, it is possible to realize a dynamic range DR3 which is wider than a dynamic range DR2 with the MOSFET diode-connected.

This gradual control may be used in combination with multi-exposure control. Multi-exposure control is a control of gradually shortening an exposure period of time during which the saturation occurs, until an exposure period of time when no saturation occurs. The gate voltage control circuit 10 may increase the amount of current by raising the gate voltage in linkage with the switching timing of the exposure time.

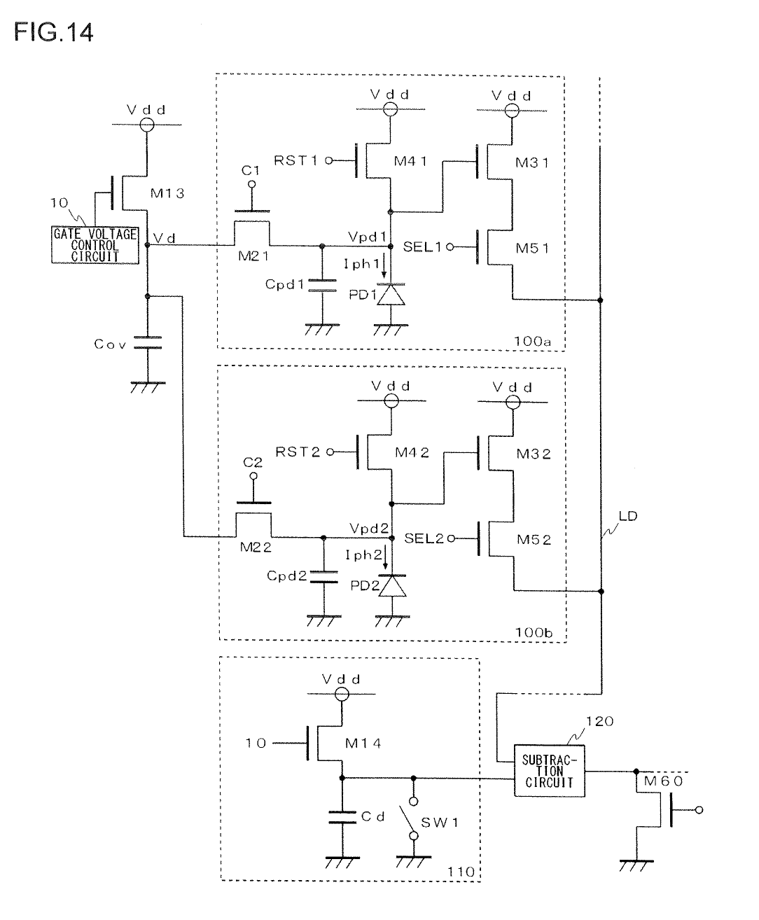

FIG. 14 is a circuit diagram showing a structure of a photo detecting apparatus provided with a pixel circuit according to the third modification. This photo detecting apparatus includes a pixel circuit 100 according to the third modification, a dummy pixel circuit 110, and a subtraction circuit 120. The dummy pixel circuit 110 functions as a current monitoring circuit for monitoring a current sent by the current control transistor M13 in the pixel circuit according to the third modification.

The dummy pixel circuit 110, which includes a dummy capacitor Cd, a dummy transistor M14, and a switch SW1, detects a control current sent by the current control transistor M13. Connected in series between the supply voltage Vdd and the ground voltage GND are the dummy transistor M14 and the dummy capacitor Cd. The dummy transistor M14 is a dummy element for the current control transistor M13, whereas the dummy capacitor Cd is a dummy element for the overflow drain capacitor Cov. The dummy transistor M14 has a drain terminal thereof coupled to one end of the dummy capacitor Cd; the supply voltage Vdd is applied to a source terminal thereof; and a bias voltage identical to one applied to the current control transistor M11 is applied to a gate terminal thereof from the gate voltage control circuit 10. The switch SW2 is connected between the ground GND and a path connecting a connection point between the dummy transistor M14 and the dummy capacitor Cd and the subtraction circuit 120. Note, however, that if the characteristic of the dummy capacitor Cd and the charge storage time are set the same way as for the overflow capacitor Cov, the possibility of saturation will increase, so that it may be necessary to employ a shorter storage period or a larger area of the dummy capacitor Cd. For example, the storage time may be set 1/10 of that for the overflow capacitor Cov, or the area of the dummy capacitor Cd may be ten times larger than that for the overflow capacitor Cov.

The dummy pixel circuit 110 operates as described below. Prior to the start of an exposure period for the first pixel circuit 100a, the switch SW1 is turned on, and the dummy capacitor Cd is reset to the ground voltage GND. Then, as the switch SW1 is turned off, the dummy capacitor Cd stores charge of the control current sent by the dummy transistor M14.

The subtraction circuit 120 functions as a correction circuit for correcting the output voltage of the first pixel circuit 100a by subtracting the output voltage of the dummy pixel circuit 110 therefrom. The voltage after the correction, on account of a correction of the control current, assumes a voltage reflecting the actual amount of light received. These voltages are represented by Equations (1) to (3).

Output voltage of the first pixel circuit 100a=(Iph1−Ict1)Δt/(Cpd1+Cov) Equation (1)

Output voltage of dummy pixel circuit 110=Ict2/Cd×1/N≈−Ict1/(Cpd1+Cov)×1/N Equation (2)

Voltage after correction=(Iph1−Ict1)/(Cpd1+Cov)−{−Ict1/(Cpd1+Cov)×1/N}×N=Iph1/(Cpd1+Cov) Equation (3)

where Iph1 is photocurrent flowing through the photodiode PD1, Ict1 a current sent by the current control transistor M13, Δt a storage time, Ict2 a current sent by the dummy transistor M14, Cpd1 a capacitance value of the cathode capacitance Cpd1, Cov a capacitance value of the overflow capacitor Cov, Cd a capacitance value of the dummy capacitor Cd, and N an adjusted value of area and storage time of the dummy capacitor Cd. As mentioned above, if the area of the dummy capacitor Cd is made ten times larger, then an adjustment is necessary in which the output voltage of the dummy pixel circuit 110 is increased by ten times.

It is to be noted that since the output voltage of the first pixel circuit 100a is amplified by the amplifier transistor M31, there is a need to adjust one of the above-mentioned voltages. Such an adjustment is not represented in the above Equations (1) to (3). Also, the arrangement may be such that the output voltages of the first pixel circuit 100a and the dummy pixel circuit 110 are converted into digital signals and thus the signals corresponding to the actual amount of received light are obtained as digital signals through digital operation.

As described above, according to the third modification, it is possible to adjust the amount of charge to be stored in the overflow drain capacitor Cov by connecting a MOSFET to the terminal of the overflow drain capacitor Cov, which is on the side where the overflow drain capacitor Cov is coupled to the cathode terminal of the photodiode PD1 and controlling the gate voltage thereof. Thus a wider dynamic range can be realized while suppressing the increase in circuit area. Also, this third modification provides greater freedom of design than the first and second modifications. Moreover, the provision of a dummy pixel circuit makes it possible to remove with accuracy the current sent to increase the saturation charge amount.

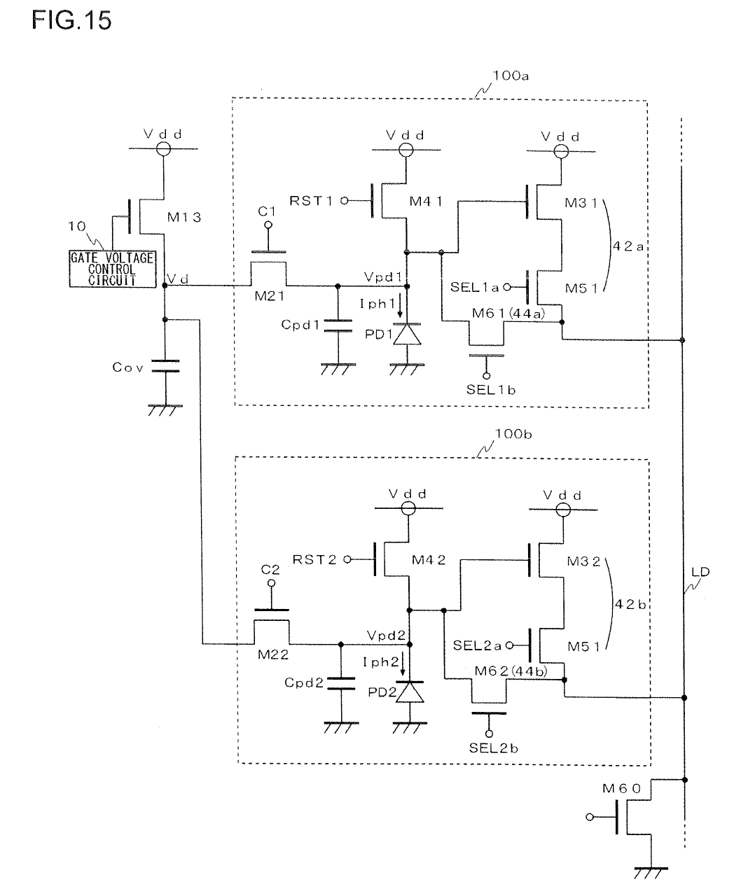

A fourth modification will now be described FIG. 15 is a circuit diagram showing a structure of a photo detecting apparatus provided with a pixel circuit according to a fourth modification. The basic structure shown in FIG. 2 and the structure shown in the first to third modifications represent a pixel circuit of an active pixel sensor (APS) system. In the fourth modification, a description will be given of a pixel circuit which is adaptable to a passive pixel sensor (PPS) system in addition to an APS system. It should be noted here that a component to realize a PPS system is added to the pixel circuit according to the third modification the in FIG. 15, but a similar arrangement may be applicable to the pixel circuit shown in FIG. 2 and the pixel circuits according to the first and second modifications as well.

In FIG. 15, the first pixel circuit 100a includes a first detector 42a and a second detector 44a as a detection circuit. The first pixel circuit 100a is configured such that a first mode in which the first detector 42a becomes active and a second mode in which the second detector 44a becomes active are switchable with each other. Similarly, the second pixel circuit 100b includes a first detector 42b and a second detector 44b as a detection circuit. The second pixel circuit 100b is configured such that a first mode in which the first detector 42b becomes active and a second mode in which the second detector 44b becomes active are switchable with each other. A description will be given of the first pixel circuit 100a as an example but the similar description applies to the second pixel circuit 100b.

The first detector 42a, which corresponds to the APS system, includes an amplifier transistor M31 and a selector transistor M51 as described earlier. The first detector 42a amplifies, by a source follower amplifier, a voltage appearing at the cathode capacitance Cpd1 caused by a photocurrent Iph1 flowing through the photodiode PD1 and outputs it to the data line LD.

The second detector 44a is constructed by including a charge output transistor M61. The charge output transistor M61 is provided on a path leading from the cathode terminal of the photodiode PD1 to a data line LD to which the first pixel circuit 100a is connected. The second detector 44a, which corresponds to the PPS system, outputs via the data line LD a charge stored in the cathode capacitance Cpd1 or the composite capacitance of the cathode capacitance Cpd1 and the overflow drain capacitor Cov by the photocurrent Iph1 flowing through the photodiode PD1.

The APS system and the PPS system may be switched therebetween for use, depending on the amount of light received. The APS system, which allows amplification by the amplifier transistor M31, is suited for detection of relatively weak light. On the other hand, the PPS system, which is for high illuminance, is suited for detection of relatively strong light. The dynamic range can be expanded by adaptively switching these two systems for each pixel depending on the amount of light received. Note that the first pixel circuit 100a may be constructed with the PPS system alone and, in such a case, it is not necessary to provide a first detector 42a.

As described above, according to the fourth modification, the pixel circuit employing an overflow drain capacitor Cov can be used for a PPS system. The PPS system, which provides storage time rather easily, can make the circuit less complex, smaller in scale, and less power-consuming. This fourth modification thus provides these advantageous effects while realizing a wider dynamic range. Also, with the PPS system, not the voltage but the charge can be amplified by the use of a not-shown charge amplifier provided outside the pixel circuit 100, so that there is no need for charge-voltage conversion within the pixel circuit. Hence, there is no voltage limitation at the conversion, and the charge can be stored in the pixel circuit with greater efficiency. In this case, there is no need to use an overflow capacitor Cov of high accuracy, and thus a larger capacitance may be secured within the same area. This naturally makes it easier to realize a wide dynamic range. Also, the use of a configuration which allows switching between the APS system and the PPS system makes it possible to widen the dynamic range even wider.

Other modifications will now be described. For example, the following two processings may be combined. That is, a processing of performing a control so that exposure periods do not overlap in between the pixel circuits 100 that share the capacitor as shown in the third operation example and a processing of switching the pixel circuits 100 that use the overflow drain capacitor Cov as shown in the second operation example may be combined. In such a case, the leakage of electric charge from a pixel circuit 100 where no exposure period is in progress can be further suppressed.

Also, in the above-described embodiments and modifications, the description has been given of a case where the transistors used in the pixel circuit 100 are mainly N-channel MOSFETs. However, this should not be considered as limiting and the arrangement may be such that some of the transistors is P-channel MOSFETs. In such a case, the high level and the low level of signals given to the gate are reversed as appropriate.

Also, in the above-described embodiments and modifications, the description has been about cases where the pixel circuit 100 is provided with a photodiode PD. However, any other device, such as a phototransistor, may be used instead, so long as it is a photo detecting element that changes the flow of photocurrent in response to the incident light intensity.

While the preferred embodiments of the present invention have been described using specific terms, such description is for illustrative purposes only, and it is to be understood that changes and variations may be made without departing from the spirit or scope of the appended claims.

What is claimed is:

1. A photo detecting apparatus, comprising:
a plurality of pixel circuits including a plurality of photo detecting elements, respectively, which cause photocurrent corresponding to an incident light; and
a second capacitance which charges and discharges an electric charge overflowing from a first capacitance caused by each of said photo detecting elements,
wherein the number of second capacitors is less than the number of the plurality of pixel circuits.

2. A photo detecting apparatus according to claim 1, wherein each second capacitance is shared by a plurality of pixel circuits.

3. A photo detecting apparatus according to claim 2, wherein the plurality of pixel circuits sharing said second capacitance are controlled so that exposure periods thereof do not overlap with one another.

4. A photo detecting apparatus according to claim 2, wherein the plurality of pixel circuits sharing the second capacitance include a pixel circuit electrically conducting with said second capacitance and a pixel circuit not electrically conducting therewith, and
the pixel circuit electrically conducting with said second capacitance is switched frame by frame.

5. A photo detecting apparatus according to claim 3, wherein the plurality of pixel circuits sharing the second capacitance include a pixel circuit electrically conducting with said second capacitance and a pixel circuit not electrically conducting therewith, and
the pixel circuit electrically conducting with said second capacitance is switched frame by frame.

6. A photo detecting apparatus according to claim 2, wherein a plurality of pixel circuits constituting an image pickup area include a plurality of kinds of pixel circuits that output different color signals, respectively, and
the number of the plurality of kinds of pixel circuits conducting with said second capacitance is retained at a predetermined ratio among frames.

7. A photo detecting apparatus according to claim 3, wherein a plurality of pixel circuits constituting an image pickup area include a plurality of kinds of pixel circuits that output different color signals, respectively, and
the number of the plurality of kinds of pixel circuits conducting with said second capacitance is retained at a predetermined ratio among frames.

8. A photo detecting apparatus according to claim 1, wherein a plurality of pixel circuits constituting an image pickup area include a green pixel circuit for outputting a signal corresponding to a green component, a blue pixel circuit for outputting a signal corresponding to a blue component and a red pixel circuit for outputting a read component, and
the number of green pixel circuits electrically conducting with said second capacitance is greater than or equal to the total number of blue pixel circuits and red pixel circuit circuits electrically conducting with said second capacitance.

9. A photo detecting apparatus according to claim 2, wherein a plurality of pixel circuits constituting an image pickup area include a green pixel circuit for outputting a signal corresponding to a green component, a blue pixel circuit for outputting a signal corresponding to a blue component and a red pixel circuit for outputting a read component, and
the number of green pixel circuits electrically conducting with said second capacitance is greater than or equal to the total number of blue pixel circuits and red pixel circuit circuits electrically conducting with said second capacitance.

10. A photo detecting apparatus according to claim 1, wherein an output value of a saturating pixel circuit is estimated from an output value of a surrounding nonsaturated pixel circuit.

11. A photo detecting apparatus according to claim 2, wherein an output value of a saturating pixel circuit is estimated from an output value of a surrounding nonsaturated pixel circuit.

12. A photo detecting apparatus according to claim 2, further comprising:
a current control element, connected to a terminal of said second capacitance on a side where the electric charge flows in, which delivers a current to cancel part of an electric charge when the electric charge overflowing from the first capacitance is stored in said second capacitance; and
a detection circuit which detects a signal corresponding to an electric charge stored in the first capacitance and said second capacitance.

13. A photo detecting apparatus according to claim 4, further comprising:
a current control element, connected to a terminal of said second capacitance on a side where the electric charge flows in, which delivers a current to cancel part of an electric charge when the electric charge overflowing from the first capacitance is stored in said second capacitance; and
a detection circuit which detects a signal corresponding to an electric charge stored in the first capacitance and said second capacitance.

14. A photo detecting apparatus according to claim 12, wherein a drain terminal of said current control element is connected to said second capacitance, a predetermined fixed potential is applied to a source terminal thereof, and said current control element is formed by a P-channel transistor where a gate terminal and the drain terminal are diode-connected.

15. A photo detecting apparatus according to claim 12, wherein a source terminal of said current control element is connected to said second capacitance, a predetermined fixed potential is applied to a drain terminal thereof, and said current control element is formed by an N-channel transistor where a gate terminal and the source terminal are diode-connected.

16. A photo detecting apparatus according to claim 12, wherein said current control element is formed by a transistor, and said current control element is such that a current by which to cancel part of an electric charge overflowing from the first capacitance is controlled by controlling a gate voltage of the transistor.

17. A photo detecting apparatus according to claim 12, further comprising:
a current monitoring circuit which monitors a current delivered by said current control element wherein said current monitoring circuit is provided with a dummy capacitance and a dummy transistor corresponding respectively to said second capacitance and said current control element; and
a correction circuit which removes a signal component read out by said current monitoring circuit, from a signal read out from said detection circuit.

18. A photo detecting apparatus according to claim 14, further comprising:
a current monitoring circuit which monitors a current delivered by said current control element wherein said current monitoring circuit is provided with a dummy capacitance and a dummy transistor corresponding respectively to said second capacitance and said current control element; and
a correction circuit which removes a signal component read out by said current monitoring circuit, from a signal read out from said detection circuit.

19. A photo detecting apparatus according to claim 15, further comprising:
a current monitoring circuit which monitors a current delivered by said current control element wherein said current monitoring circuit is provided with a dummy capacitance and a dummy transistor corresponding respectively to said second capacitance and said current control element; and
a correction circuit which removes a signal component read out by said current monitoring circuit, from a signal read out from said detection circuit.

20. A photo detecting apparatus according to claim 1, wherein a pixel circuit where the photo detecting element is connected to said second capacitance and a pixel circuit where the photo detecting element is no connected to said second capacitance are mixed in the plurality of pixel circuits.
